(19) United States
(12) Patent Application Publication
(10) Pub. No.: US 2017/0254930 A1
(43) Pub. Date: Sep. 7, 2017

(54) STRUCTURED LIGHT-TRANSMITTING ARTICLES AND METHODS FOR MAKING THE SAME

(71) Applicant: Corning Incorporated, Corning, NY (US)

(72) Inventors: Shandon Dee Hart, Corning, NY (US); Karl William Koch, III, Elmira, NY (US); Jen-Chieh Lin, Zhubei City (TW); Mark Alejandro Quesada, Horseheads, NY (US); James Andrew West, Painted Post, NY (US)

(21) Appl. No.: 15/448,022

(22) Filed: Mar. 2, 2017

Related U.S. Application Data
(60) Provisional application No. 62/303,043, filed on Mar. 3, 2016.

(51) Int. Cl. G02B 5/02; H01L 51/52; C03C 17/00

(52) U.S. Cl. CPC G02B 5/0221; C03C 17/001; G02B 5/0278; H01L 51/5268; H01L 51/5281

(57) ABSTRACT

Disclosed herein are methods for forming light-transmitting articles comprising depositing a layer comprising a second material on a substrate comprising a first material, and forming a patterned surface on the second material. The first and second materials can have different glass transition temperatures Tg and/or refractive indices n. Additional layers comprising a third material can also be formed over the patterned surface, the third material having a glass transition temperature Tg and refractive index n that may be the same or different from those of the first and second material. Light-transmitting articles formed by such methods, as well as display devices comprising such light-transmitting articles are also disclosed herein.

This application claims the benefit of priority under 35 U.S.C. §119 of U.S. Provisional Application Ser. No. 62/303,043 filed on Mar. 3, 2016, the content of which is relied upon and incorporated herein by reference in its entirety.

### FIELD OF THE DISCLOSURE

The disclosure relates generally to light-transmitting articles comprising one or more patterned surfaces, and more particularly to light-diffusing and light-extracting articles comprising at least one low glass transition temperature (Tg) glass, and methods for making the same.

### BACKGROUND

Glass substrates with textured, structured, or otherwise patterned surfaces are useful for a wide variety of applications, for example they may be used for light management in display applications. Textured glass substrates can be used, for example, to scatter light, diffuse light, extract light, direct light, or reflect light, to name a few useful applications. Moreover, textured glass substrates can be utilized as anti-glare media, touch-sensing media, image projection media, information display media, and other like applications.

Current methods for texturing a surface of a glass substrate or an interface between glass substrates, e.g., photolithography and/or etching processes, tend to be costly, complex, and/or potentially damaging. Furthermore, most methods for structuring a glass article are limited to spatial structuring of a single glass substrate and do not enable methods to structure other physical properties of the glass article, such as the refractive index. For example, typical texturing processes result in an article incorporating only two refractive indices, e.g., the refractive index of the article itself and that of air.

Accordingly, it would be advantageous to provide methods for structuring one or more surfaces of a light-transmitting article without using photolithography or etching techniques. It would also be advantageous to provide methods for structuring both the spatial morphology and the refractive index of a light-transmitting article, for instance, producing an article incorporating at least three refractive indices (e.g., a first layer, a second layer, and air).

### SUMMARY

The disclosure relates, in various embodiments, to methods for forming a light-transmitting article, the methods comprising depositing a second transparent material on a substrate comprising a first transparent material to form a composite, wherein the first transparent material has a first glass transition temperature Tg1 and a first refractive index n1 and the second transparent material having a second glass transition temperature Tg2 and a second refractive index n2; heating the composite to a temperature greater than Tg2; and forming a patterned surface on the second transparent material, wherein Tg1>Tg2 and n2>n1. In some embodiments, Tg1>550° C. and 200° C.<Tg2<600° C.

According to various embodiments, the second transparent material can be deposited by reactive or non-reactive vapor deposition, lamination, fusion forming, frit deposition followed by sintering, and sol-gel processes. Exemplary vapor deposition processes can comprise chemical vapor deposition (CVD) plasma-enhanced CVD (PECVD), sputtering, multi-source thermal evaporation, or e-beam evaporation. A patterned surface can be formed on the second transparent material, for example, by at least one of stamping, embossing, molding, replicating, imprinting, thermal self-patterning, phase separation, film dewetting, laser patterning, or self-assembly. The patterned surface can be continuous, semi-continuous, or discontinuous and can, in various embodiments, comprise a plurality of peaks and valleys and/or a plurality of peaks and voids.

In additional embodiments, a third transparent material having a third glass transition temperature Tg3 and a third refractive index n3 can be deposited on the patterned surface, e.g., in one or more of the valleys, on one or more of the peaks, and/or in one or more of the voids. The first Tg1 can, in various embodiments be greater than the third Tg3 and, in other embodiments, the second Tg2 can be greater than the third Tg3 but less than the first Tg1. Similarly, the third refractive index n3 can be greater than the first refractive index n1, and the second refractive index n2 can be greater than the first refractive index n1 but less than the third refractive index n3.

Also disclosed herein are methods for forming a light-transmitting article, the methods comprising depositing a second material on a substrate comprising a first material, wherein the first material is transparent and has a first glass transition temperature Tg1 and a first refractive index n1, and wherein the second material has a second glass transition temperature Tg2 and a second refractive index n2; forming a patterned surface on the second material; and depositing a third material on the patterned surface, wherein the third material is transparent and has a third glass transition temperature Tg3 and a third refractive index n2, and wherein n1, n2, and n3 have different values.

The second Tg2 can, in some embodiments, be greater than or equal to the first Tg1 and/or the second refractive index n2 can be greater than the first refractive index n1. The third Tg3 may be less than the first Tg1 and/or the second Tg2 and/or the third refractive index n3 may be greater than the second refractive index n2 and/or the first refractive index n1. According to some embodiments, the second material can comprise glass, polymer, dielectric, metal, metal oxide, or metal nitride materials. The third material can be deposited on the patterned surface, for instance, in one or more voids of the patterned surface or, in other embodiments, a surface of the third material may be planarized. In various embodiments, the third material can comprise a low Tg glass.

Further disclosed herein are light-transmitting articles comprising a substrate comprising a first transparent material having a first glass transition temperature Tg1 and a first refractive index n1; a first layer comprising a second transparent material having a second glass transition temperature Tg2 and a second refractive index n2, and a second layer comprising a third transparent material having a third glass transition temperature Tg3 and a third refractive index n3, wherein an interface between the first layer and the second layer is patterned, and wherein Tg1>Tg2>Tg3 and n3>n2≧n1. In certain embodiments, Tg1>550° C.; 400° C.<Tg2<600° C.; and 200° C.<Tg3<500° C. According to various embodiments, the article may be a light-diffusing article and the second layer may be disposed in one or more valleys or voids of the patterned surface. In other embodiments, the article may be a light-extracting article and the second layer may comprise a substantially planar surface. Display devices comprising such articles are also disclosed herein.

Additional features and advantages of the disclosure will be set forth in the detailed description which follows, and in part will be readily apparent to those skilled in the art from that description or recognized by practicing the methods as described herein, including the detailed description which follows, the claims, as well as the appended drawings.

It is to be understood that both the foregoing general description and the following detailed description present various embodiments of the disclosure, and are intended to provide an overview or framework for understanding the nature and character of the claims. The accompanying drawings are included to provide a further understanding of the disclosure, and are incorporated into and constitute a part of this specification. The drawings illustrate various embodiments of the disclosure and together with the description serve to explain the principles and operations of the disclosure.

### BRIEF DESCRIPTION OF THE DRAWINGS

The following detailed description can be further understood when read in conjunction with the following drawings.

FIG. 1 illustrates a light-diffusing article according to various embodiments of the disclosure;

FIG. 2 illustrates a light-extracting article according to certain embodiments of the disclosure; and

FIG. 3 illustrates a display device comprising a light-transmitting article according to additional embodiments of the disclosure;

FIG. 4 illustrates an exemplary method for forming a light-transmitting article according to certain embodiments of the disclosure; and

FIG. 5 illustrates another exemplary method for forming a light-transmitting article according to further embodiments of the disclosure.

FIG. 6 illustrates another exemplary method for forming a light-transmitting article according to embodiments of the disclosure.

### DETAILED DESCRIPTION

Articles

Disclosed herein are articles comprising a substrate comprising a first transparent material having a first glass transition temperature Tg1 and a first refractive index n1; a first layer comprising a second transparent material having a second glass transition temperature Tg2 and a second refractive index n2; and a second layer comprising a third transparent material having a third glass transition temperature Tg3 and a third refractive index n3, wherein an interface between the first layer and the second layer is patterned, and wherein Tg1>Tg2>Tg3 and n3>n2≧n1. Also disclosed herein are light-diffusing articles in which the second layer may be disposed in one or more valleys or voids of the patterned surface. Further disclosed herein are light-extracting articles in which the second layer may comprise a substantially planar surface. Still further disclosed herein are display devices comprising such articles.

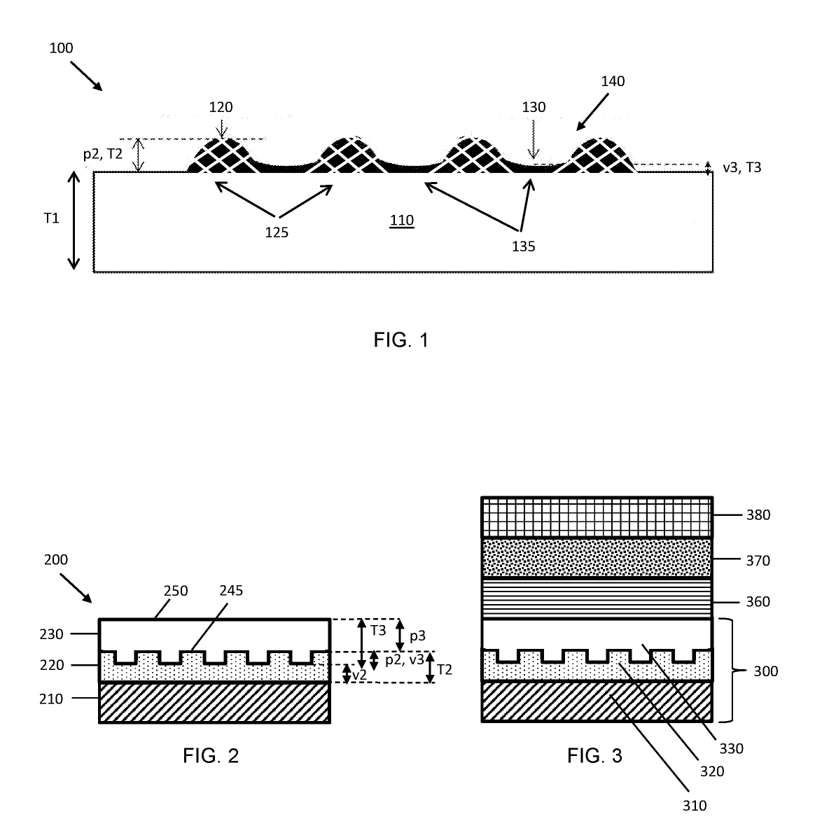

The articles and devices disclosed herein will generally be discussed with reference to FIGS. 1-3, which illustrate various light-transmitting articles and display devices incorporating such articles according to non-limiting embodiments of the disclosure. The following general description is intended to provide an overview of the claimed articles and devices. Various aspects will be more specifically discussed throughout the disclosure with reference to the non-limiting embodiments, these embodiments being interchangeable with one another within the context of the disclosure

FIGS. 1-2 depict light-transmitting articles, such as light-diffusing article 100 and light-extracting article 200, according to various embodiments of the disclosure. The articles 100, 200 can comprise a substrate 110, 210 comprising a first transparent material, a first layer 120, 220 comprising a second transparent material, and a second layer 130, 230 comprising a third transparent material.

Materials suitable for use as substrates 110, 210 in the methods and/or products disclosed herein can include any desired transparent material, such as glass, crystalline (e.g., sapphire), polycrystalline ceramic (e.g., spinel and zirconia), plastic, and polymer materials, and the like. In at least one non-limiting embodiment, the substrate 110, 210 can be a glass substrate. Exemplary glass substrates can comprise, for example, any glass known in the art that is suitable for graphene deposition and/or display devices including, but not limited to, aluminosilicate, alkali-aluminosilicate, alkaline earth aluminosilicate, borosilicate, alkali-borosilicate, alkaline earth borosilicate, aluminoborosilicate, alkali-aluminoborosilicate, alkaline earth aluminoborosilicate, soda lime silicate, and other suitable glasses. Non-limiting examples of commercially available glasses suitable for use as a substrate include, for instance, EAGLE XG®, Iris™, Lotus™, Willow®, Gorilla®, HPFS®, and ULE® glasses from Corning Incorporated. Suitable glasses are disclosed, for example, in U.S. Pat. Nos. 4,483,700, 5,674,790, and 7,666,511, which are incorporated herein by reference in their entireties.

In certain embodiments, the substrate 110, 210 may have a thickness T1 of less than or equal to about 3 mm, for example, ranging from about 0.1 mm to about 2.5 mm, from about 0.3 mm to about 2 mm, from about 0.7 mm to about 1.5 mm, or from about 1 mm to about 1.2 mm, including all ranges and subranges therebetween. The substrate 110, 210 can, in some embodiments, comprise a glass sheet having a first surface and an opposing second surface. The surfaces may, in certain embodiments, be planar or substantially planar, e.g., substantially flat and/or level. The substrate can also, in some embodiments, be curved about at least one radius of curvature, e.g., a three-dimensional substrate, such as a convex or concave substrate. The first and second surfaces may, in various embodiments, be parallel or substantially parallel. The substrate may further comprise at least one edge, for instance, at least two edges, at least three edges, or at least four edges. By way of a non-limiting example, the substrate 110, 210 may comprise a rectangular or square sheet having four edges, although other shapes and configurations are envisioned and are intended to fall within the scope of the disclosure.

The first layer 120, 220 and/or second layer 130, 230, if present, can likewise comprise any desired transparent material, such as glass, crystalline (e.g., sapphire), polycrystalline ceramic (e.g., spinel and zirconia) plastic, polymer, dielectric, metal oxide, and metal nitride materials, and the like. In some embodiments, the first and/or second layer can comprise a glass, such as a glass having a low glass transition temperature, which are discussed in more detail below. Exemplary glasses can include, without limitation, zinc bismuth borate, zinc phosphate, alkali zinc phosphate, alkali zinc sulfophosphate, zinc borophosphate, tin borophosphate, antimony germanate, tellurite, alkali tin aluminum fluorophosphates, alkali tantalum borophosphate, alkali borophosphate, tin silicate, alkaline earth aluminoborate, alkali aluminophosphate, and alkaline earth aluminophosphate glasses, to name a few. Some non-limiting examples of suitable glass materials for the first and/or second layers 120, 130, 220, 230 are listed in Table I below, along with their respective refractive indices, glass transition temperatures (Tg), and softening temperatures (Ts).

TABLE I
Exemplary Glass Compositions

| Glass Family/Composition (mol % unless | Refr. | | |
|---|---|---|---|
| otherwise noted) | Index | Tg (° C.) | Ts (° C.) |
| Zinc Bismuth Borates: | | | |
| 10ZnO—30Bi2O3—60B2O3 | 1.93 | 466 | |
| 30ZnO—30Bi2O3—40B2O3 | 2.02 | 421 | |
| Zinc Phosphates and Borophosphates: | | | |
| 45ZnO—30Bi2O3—25P2O5 | 1.966 | 450 | |
| 3Li2O—3ZnO—55TiO2—12B2O3—27P2O5 | 1.835 | 551 | |
| 30•P2O5—30•ZnO—40•B2O3 | | 506 | 562 |
| 30•P2O5—60•ZnO—10•B2O3 | | 399 | 424 |
| 9.2•P2O5—68.4•ZnO—22.4•B2O3 | 1.69 | 509 | 579 |
| 28.5•P2O5—62.7•SnO—6.3•ZnO—0.5•Al2O3—2.0•B2O3 | | ~275 | |
| 30.3•P2O5—43.9•SnO2—21.9•ZnO—3.8•B2O3 | | 332 | |
| Alkali Zinc Sulfophosphate: | | | |
| 24.8•P2O5—40.7•ZnO—12.5•SO3—1.5•Al2O3—8•Na2O—5.3•Li2O—5.8•K2O—0.7•CaO—0.7•SrO | | 300 | |
| (wt %) | | | |
| Tin borophosphate: | | | |
| 23.3P2O5—67•SnO—10•B2O3 | 1.84 | 305 | |
| 90•(33.3•P2O5—66.7•SnO)—10•B2O3 | 1.78 | 330 | |
| Antimony Germanate: | | | |
| 67GeO2—33Sb2O3 | 1.82 | 380 | |
| Tellurites: | | | |
| 83.4TeO2—8.5La2O3—1.2B2O3—0.3K2O—3.2Ta2O5—3.4GeO2 | 2.1 | | |
| 70TeO2—30ZnO | 2.08 | 320 | 335 |
| Alkali Tin Aluminum Flourophosphate: | | | |
| 27.9 P2O5—29.6 NH4PF6—33.3 SnF2—9.5AlF3•H2O (Batch wt %) | 1.8 | 230 | |
| Alkali Tantalum Borophosphate: | | | |
| 10Ta2O5—30P2O5—10B2O3—30Li2O—20Na2O | 1.624 | 405 | |
| Tin Silicates: | | | |
| 29.6SnO—70.4SiO2 | 1.657 | 485 | 517 |
| Alkaline earth aluminoborates: | | | |
| 10BaO—10Al2O3—80B2O3 | | 475 | |
| 50BaO—10Al2O3—40B2O3 | | 510 | |
| 17•CaO—8.4•Al2O3—74.6•B2O3 | 1.535 | ~575 | |
| Alkali/alkaline earth aluminophosphate: | | | |
| 20Al2O3—80(NaPO3) | | 405 | |
| 29.2•BaO—12.2•Al2O3—52.6•P2O5—2.4•SiO2 | 1.56 | 548 | 576 |
| Alkali Borophosphate: | | | |
| 10•B2O3—90(NaPO3) | 1.49 | 358 | |
| 50•B2O3—50(NaPO3) | 1.51 | 439 | |

In certain embodiments, referring to FIGS. 1-2, the first layer 120, 220 may have an average peak height p2 (e.g., as measured from the lowest point in the second layer, such as a valley or void, to the highest point in the layer, such as a peak) ranging from about 1 nm to about 10 μm, for example, from about 5 nm to about 5 μm, from about 10 nm to about 2 μm, from about 20 nm to about 1 μm, from about 50 nm to about 900 nm, from about 100 nm to about 800 nm, from about 200 nm to about 700 nm, from about 300 nm to about 600 nm, or from about 400 nm to about 500 nm, including all ranges and subranges therebetween. In additional embodiments, referring to FIGS. 1-2, the first layer 120, 220 may have an overall thickness T2 (e.g., as measured from the interface with the substrate 110, 210 to the highest point in the layer, such as a peak), which may be equal to v2+p2, where v2 is the valley or void height. For example, T2 may range from about 1 nm to about 10 μm, for example, from about 5 nm to about 5 μm, from about 10 nm to about 2 μm, from about 20 nm to about 1 μm, from about 50 nm to about 900 nm, from about 100 nm to about 800 nm, from about 200 nm to about 700 nm, from about 300 nm to about 600 nm, or from about 400 nm to about 500 nm, including all ranges and subranges therebetween. As shown in FIG. 1, in the case of a first layer comprising peaks 125 and voids 135 (e.g., v2=0), p2 and T2 may have the same value.

Similarly, referring again to FIGS. 1-2, the second layer 130, 230 may have an overall average valley or void thickness v3 (e.g. as measured from the interface with the first layer 120, 220 in the case of a continuous first layer or as measured from the interface with the substrate 110, 210 in the case of a discontinuous first layer, respectively), and v3 may range from about 1 nm to about 10 μm, for example, from about 5 nm to about 5 μm, from about 10 nm to about 2 μm, from about 20 nm to about 1 μm, from about 50 nm to about 900 nm, from about 100 nm to about 800 nm, from about 200 nm to about 700 nm, from about 300 nm to about 600 nm, or from about 400 nm to about 500 nm, including all ranges and subranges therebetween. Although not illustrated in FIG. 1, the second layer 130 may also coat one or more of the peaks 125 (see FIG. 2). In some embodiments, the thickness v3 of the second layer 130 in the valley or voids 135 of the first layer 120 can be greater than the thickness (p3, not illustrated in FIG. 1) of the second layer 130 on the peaks 125. For example, the peak thickness p3 may range from about 1 nm to about 1000 nm, such as from about 5 nm to about 500 nm, from about 10 nm to about 400 nm, from about 50 nm to about 300 nm, or from about 100 nm to about 200 nm, including all ranges and subranges therebetween.

Referring to FIGS. 1-2, the second layer 130, 230 may have an overall thickness T3 (e.g., as measured from the interface with the first layer in the case of a continuous first layer or as measured from the interface with the substrate in the case of a discontinuous first layer), which may be equal to v3+p3, for example, ranging from about ranging from about 1 nm to about 10 μm, for example, from about 5 nm to about 5 μm, from about 10 nm to about 2 μm, from about 20 nm to about 1 μm, from about 50 nm to about 900 nm, from about 100 nm to about 800 nm, from about 200 nm to about 700 nm, from about 300 nm to about 600 nm, or from about 400 nm to about 500 nm, including all ranges and subranges therebetween. As shown in FIG. 1, in the case of a second layer 130 that is not deposited on peaks 125 (e.g., p3=0), v3 and T3 may have the same value. In additional embodiments, T3 T2, e.g., as depicted in FIG. 2. In further embodiments, T3<T2, e.g., as depicted in FIG. 1.

The first layer 120, 220 may form a pattern on a surface of the substrate 110, 210 which can be regular or irregular, repeating or random, continuous, semi-continuous, or discontinuous. As shown in FIG. 1, the first layer 120 may have a peak-void pattern, in which the first layer forms spaced-apart peaks 125, e.g., islands separated by voids 135. While FIG. 1 illustrates a regular, repeating pattern of identical, evenly spaced-apart peaks 125, it is to be understood that the peaks can also have varying heights and/or widths, can be spaced apart by varying distances, and can form an irregular, non-repeating pattern on the substrate 110.

As shown in FIG. 2, the first layer 220 can also have a peak-valley pattern, in which the first layer forms spaced-apart peaks and valleys, e.g., alternating regions of varying thickness (v2, p2). While FIG. 2 illustrates a regular, repeating pattern of identical, evenly spaced-apart peaks and valleys, it is to be understood that the peaks and/or valleys can also have varying heights and/or widths, can be spaced apart by varying distances, and can form an irregular, non-repeating pattern on the substrate 210. Furthermore, the shape of the peaks and/or valleys of the first layer 120, 220 are not limited and can have any regular or irregular shape, for instance, rounded peaks as shown in FIG. 1 or squared peaks as shown in FIG. 2, to name a few. According to various embodiments, a surface of the first layer 120, 120 can be structured to have a desired shape and/or pattern suitable for any desired application, e.g., light-transmitting applications such as light diffusion and light extraction.

As shown in FIG. 1, the second layer 130, when present, can overlay or otherwise modify the surface of the first layer 120 to form a patterned surface 140. For instance, the second layer 130 can be disposed in voids 135 between peaks 125 of the first layer 120. Alternatively, although not illustrated in FIG. 1, the second layer 130 can be disposed both in the voids 135 and on the peaks 125. The thickness of the second layer in the voids/valleys and on the peaks (v3, p3) can be the same or different. In some embodiments, the thicknesses are different and, in further embodiments, the void/valley thickness v3 may be greater than the peak thickness p3.

Light-diffusing articles and their general properties are disclosed, for instance, in U.S. patent application Ser. Nos. 14/413,158 and 14/563,228, which are incorporated herein by reference in their entireties. According to various embodiments light-diffusing articles disclosed herein can be engineered such that the thicknesses and refractive indices of the first and second layers satisfy the following equation:

(T2)(n2)=(T3)(n3)+(T2−T3)(n0)

where n0 is the refractive index of the external medium (e.g., n0=1 for air). T2 and T3, e.g., the thickness of the first and second layers, respectively, represent the physical path length for light traveling through these layers. Light-diffusing articles satisfying the above equation may advantageously preserve optical phase matching in transmission.

As illustrated in FIG. 2, the second layer 230 can also overlay or otherwise modify the surface of the first layer 220 to form a substantially planar top surface 250 and a patterned interface 245. For example, the second layer 230 can coat or overlay both the peaks and valleys (or voids) of the first layer 220 such that the top surface of the second layer 230 is substantially planar (e.g., v2+p3≈p2+p3).

The articles 100 and 200 (and individual components 110, 120, 130, 210, 220, 230) can, in various embodiments, be transparent or substantially transparent. As used herein, the term “transparent” is intended to denote that the article, substrate, material, and/or layer, at a thickness of approximately 1 mm, has a transmission of greater than about 70% in the visible region of the spectrum (400-700 nm). For instance, an exemplary transparent article, substrate, material, and/or layer may have greater than about 75% transmittance in the visible light range, such as greater than about 80%, greater than about 85%, greater than about 90%, greater than about 95%, or greater than about 99% transmittance, including all ranges and subranges therebetween.

In certain embodiments, an exemplary transparent article, substrate, material, and/or layer may have a transmittance of greater than about 50% in the ultraviolet (UV) region (100-400 nm), such as greater than about 55%, greater than about 60%, greater than about 65%, greater than about 70%, greater than about 75%, greater than about 80%, greater than about 85%, greater than about 90%, greater than about 95%, or greater than about 99% transmittance, including all ranges and subranges therebetween. In other embodiments, one or more layers may be selected to have a low transmittance and a high absorbance in the UV range. For example, a material or layer may have less than about 20% transmittance and greater than about 80% absorbance at a selected wavelength in the UV region.

The substrate and layer(s) disclosed herein can be engineered to produce a structured article having a number of varying physical properties, e.g., varying spatial/topographical features as well as varying refractive indices and/or glass transition temperatures, or any other number of physical properties. In some embodiments, the articles disclosed herein can be engineered to have two or more refractive indices (n) and/or two or more glass transition temperatures (Tg). For example, in the case of a substrate coated with a first layer, the article may have a first glass transition temperature for the substrate (Tg1) and a second glass transition temperature for the layer (Tg2) and/or a first refractive index for the substrate (n1) and a second refractive index for the layer (n2). Similarly, a second layer may be incorporated to provide a third transition temperature (Tg3) and third refractive index (n3). Additional layers, such as third, fourth, and fifth (or more) layers may be provided to further modify the architecture of the article.

According to various embodiments, Tg1 may be greater than about 550° C., such as ranging from about 550° C. to about 3000° C., from about 600° C. to about 2500° C., from about 750° C. to about 2000° C., from about 1000° C. to about 1750° C., or from about 1250° C. to about 1500° C., including all ranges and subranges therebetween. In additional embodiments, Tg2 may range from about 200° C. to about 3000° C., such as from about 250° C. to about 2500° C., from about 300° C. to about 2000° C., from about 400° C. to about 1500° C., from about 500° C. to about 1250° C., from about 600° C. to about 1000° C., or from about 700° C. to about 800° C., including all ranges and subranges therebetween. According to further embodiments, Tg3 may range from about 200° C. to about 500° C., such as from about 225° C. to about 450° C., from about 250° C. to about 400° C., or from about 300° C. to about 350° C., including all ranges and subranges therebetween.

The refractive indices n1, n2, and n3 may each have values independently chosen from 1.45 to 2.2, such as from about 1.5 to about 2.15, from about 1.55 to about 2.1, from about 1.6 to about 2.05, from about 1.65 to about 2, from about 1.7 to about 1.95, from about 1.75 to about 1.9, or from about 1.8 to about 1.85, including all ranges and subranges therebetween. For example, n3 may range from about 1.65 to about 2.2, such as from about 1.7 to about 2.15, from about 1.75 to about 2.1, from about 1.8 to about 2.05, from about 1.85 to about 2, or from about 1.9 to about 1.95, including all ranges and subranges therebetween. Similarly, n2 may range from about 1.5 to about 1.7, such as from about 1.55 to about 1.65, or 1.6, including all ranges and subranges therebetween. Finally, n1 may range, in some embodiments, from about 1.45 to about 1.55, such as 1.5, including all ranges and subranges therebetween.

The first and/or second layers may, in some embodiments, have the compositions, refractive indices, and/or glass transition temperatures listed in Table I above. According to some embodiments, Tg1 may be greater than about 550° C., Tg2 may range from about 400° C. to about 600° C., and/or Tg3 may range from about 200° C. to about 500° C. In other embodiments, n1 may range from about 1.65 to about 2.2, n2 may range from about 1.5 to about 1.7, and/or n3 may range from about 1.45 to about 1.55. In still further embodiments, Tg1>Tg2 and/or n2>n1. According to yet further embodiments, Tg1>Tg3 and/or n3>n1. In certain embodiments, Tg2>Tg3 and/or n3>n2. According to various embodiments, Tg1>Tg2>Tg3 and/or n3>n2≧n1.

In some non-limiting embodiments, the substrate 110, 210, first layer 120, 220, and second layer 130, 230 may all comprise glass. In other embodiments, one or more of the glass substrates and/or layers may be lead-free or substantially lead free (e.g., comprising 0 wt % lead or less than about 1 wt % lead), alkali-free or substantially alkali-free (e.g., comprising 0 wt % alkali or less than about 1 wt % alkali), and/or chlorine-free, fluorine-free, substantially chlorine-free, or substantially fluorine-free (e.g., comprising 0 wt % chlorine and/or fluorine or less than 1 wt % chlorine and/or fluorine). According to further embodiments, the glass(es) making up the substrate and/or layers may have low water solubility, high optical transparency, low absorption in the visible spectrum, low crystallization tendency, and/or high scratch or abrasion resistance.

Articles disclosed herein can have a number of applications including, but not limited to, light diffusion surfaces, light extraction surfaces, anti-glare or anti-reflection surfaces, microlens arrays, cover glass for displays or electronic devices, such as liquid crystal displays (LCDs) or OLEDs, backlights for display devices, projector screens, architectural or automotive glass, high contrast ratio glass, and biological applications, such as cell culture substrates and textured micro-reactors, to name a few.

The disclosure relates, in some embodiments, to display devices comprising the articles herein described. For example, the article may be a light-diffusing article 100 (e.g., having a patterned top surface 140 as illustrated in FIG. 1 or variations thereof) or a light-extracting article 200 (e.g., having a substantially planar top surface 250 as illustrated in FIG. 2 or variations thereof). Such articles may be incorporated into a wide variety of electronics, e.g., displays, televisions, computers, laptops, phones, handheld electronics, appliances, and the like. Such devices may further comprise one or more additional layers, such as conductive oxide, e.g., transparent conducting oxide (TCO), electrode, light-emitting diode (LED), organic light-emitting diode (OLED), hole injecting, hole transporting, electron injecting, electron transporting, fluorescent, phosphorescent, and touch-sensing layers.

An exemplary OLED device is depicted in FIG. 3 and comprises, by way of a non-limiting example, a glass article 300 (comprising a substrate 310, a first layer 320, and a second layer 330), an anode (e.g., a TCO such as indium tin oxide (ITO)) 360, an OLED layer 370, and a cathode 380 (e.g., metal or metal-organic hybrid layers). Of course, either the light-diffusing article 100 of FIG. 1 or the light-extracting article 200 of FIG. 2 can be employed in the depicted display device, or any other combination of layers, as desired to form a particular display device, and without limitation.

Methods

Disclosed herein are methods for forming a light-transmitting article, the methods comprising depositing a second transparent material on a substrate comprising a first transparent material to form a composite, wherein the first transparent material has a first glass transition temperature Tg1 and a first refractive index n1 and the second transparent material having a second glass transition temperature Tg2 and a second refractive index n2; heating the composite to a temperature greater than Tg2; and forming a patterned surface on the second transparent material, wherein Tg1>Tg2 and n2>n1.

Also disclosed herein methods for forming a light-transmitting article, the methods comprising depositing a second material on a substrate comprising a first material, wherein the first material is transparent and has a first glass transition temperature Tg1 and a first refractive index n1, and wherein the second material has a second glass transition temperature Tg2 and a second refractive index n2; forming a patterned surface on the second material; and depositing a third material on the patterned surface, wherein the third material is transparent and has a third glass transition temperature Tg3 and a third refractive index n2, and wherein n1, n2, and n3 have different values.

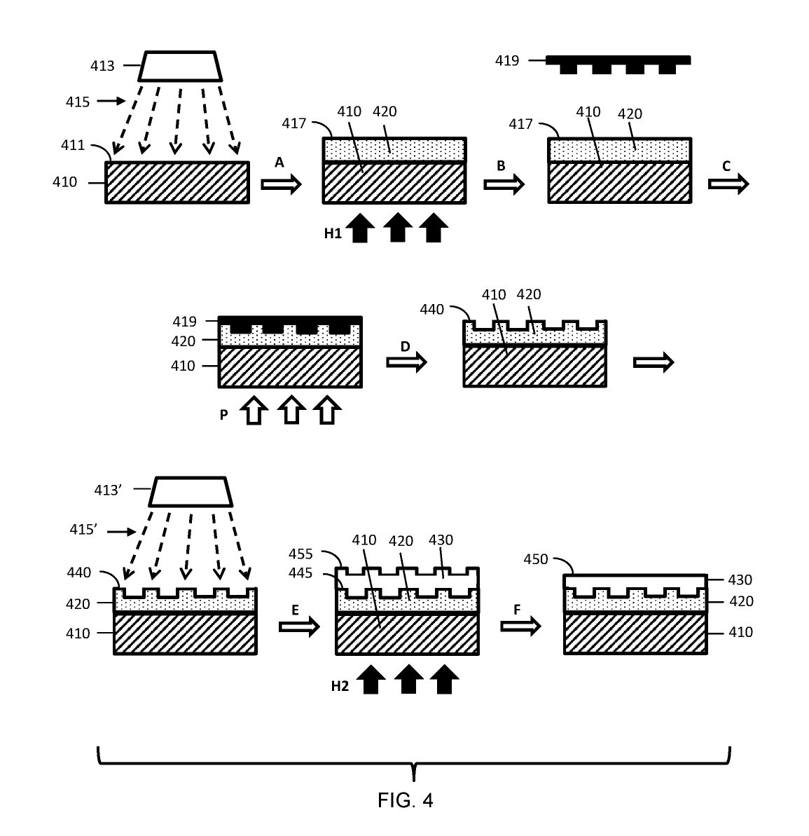

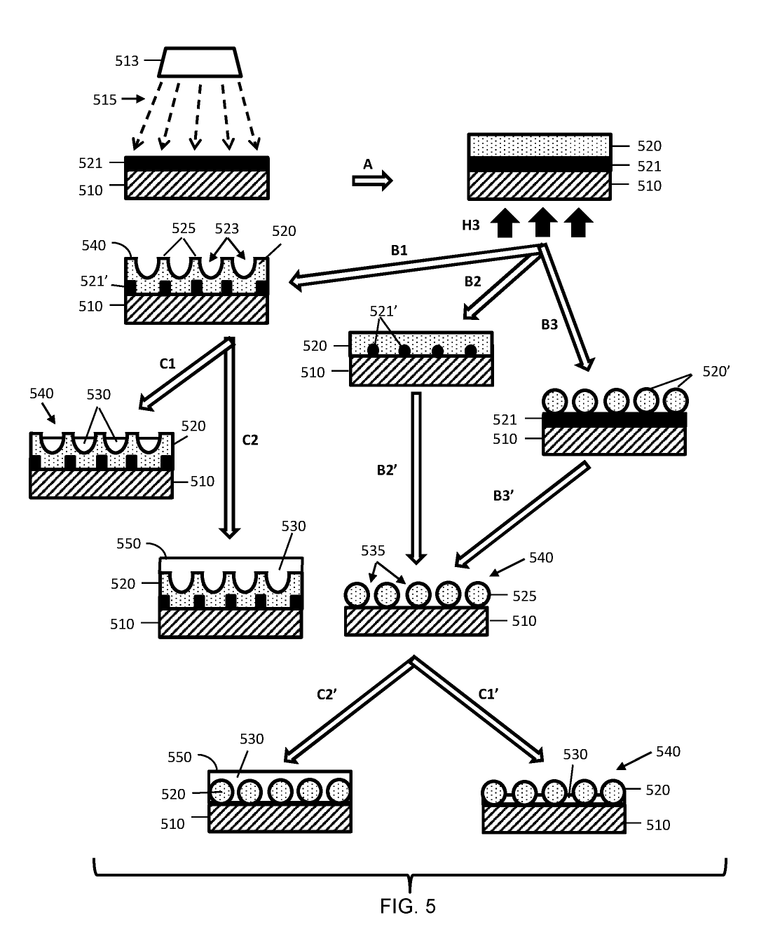

Methods disclosed herein will generally be discussed with reference to FIGS. 4-5, which illustrate various steps for forming and/or structuring layers of a light-transmitting article according to non-limiting embodiments of the disclosure. The following general description is intended to provide an overview of the claimed methods. Various aspects will be more specifically discussed throughout the disclosure with reference to the non-limiting embodiments, these embodiments being interchangeable with one another within the context of the disclosure.

As illustrated in FIG. 4, in step A, a first surface 411 of a substrate 410 can be coated, laminated, or otherwise overlaid with a first layer 420. Exemplary methods include fusion forming, laminating, frit deposition followed by sintering, sol-gel processing, and reactive or non-reactive vapor deposition methods, such as chemical vapor deposition (CVD), plasma-enhanced CVD (PECVD), sputtering, multi-source thermal evaporation, and e-beam evaporation, to name a few. According to various embodiments, the first layer 420 can be deposited on the substrate 410 such that the first layer has a thickness ranging from about 10 nm to about 10 μm, for example, from about 20 nm to about 5 μm, from about 50 nm to about 2 μm, from about 100 nm to about 1 μm, from about 200 nm to about 900 nm, from about 300 nm to about 800 nm, from about 400 nm to about 700 nm, or from about 500 nm to about 600 nm, including all ranges and subranges therebetween.

As shown in FIG. 4, in a vapor deposition process, the substrate 410 can be introduced into a chamber (not shown) along with one or more material sources 413, which can produce particles, atoms, molecules, or ions 415 (represented by dashed arrows) that are deposited on the first surface 411. While FIG. 4 illustrates a solid material source 413, it is to be understood that the at least one material source can also comprise a liquid, gas, and/or gel material, without limitation. Moreover, while FIG. 4 illustrates a vapor deposition process, it is to be understood that any suitable deposition technique, such as those described herein, can be used to form the first layer 420 on the substrate 410.

In step B, the composite comprising substrate 410 and first layer 420 may be heated to a structuring temperature, which can be any temperature sufficient to form a pattern on a surface 417 of the first layer 420. For example, heat H1 can be applied using any suitable means to raise the temperature of at least the first layer 420 and, optionally, both the first layer 420 and the substrate 410, to the structuring temperature. For example, the substrate can be placed in a microwave, furnace, or other heating device, or, in other embodiments, the second layer may be heated using a laser or other energy source. While FIG. 4 illustrates the application of heat to the substrate, heat can likewise be applied to the entire article or to only the first layer as desired and without limitation.

According to certain embodiments, the structuring temperature can be greater than the Tg of the first layer (Tg2). In other embodiments, the structuring temperature can be less than the Tg of the substrate (Tg1). According to further embodiments, the structuring temperature can be greater than the softening temperature (Ts) of the first layer (Ts2). In still further embodiments, the structuring temperature can be greater than about 200° C., such as ranging from about 250° C. to about 1000° C., from about 300° C. to about 900° C., from about 350° C. to about 800° C., from about 400° C. to about 700° C., from about 450° C. to about 600° C., or from about 500° C. to about 550° C., including all ranges and subranges therebetween.

After and/or during the heating step, the surface 417 of the first layer 420 can be patterned or otherwise structured in step C. For example, as illustrated in FIG. 4, a mold 419 can be provided, which can be used to stamp or otherwise produce a pattern in the surface 417 of the first layer 420. In some embodiments, the mold 419 can be brought into contact with surface 417 and force P can be applied either to the mold or to the substrate (or both) to press the mold 419 into the first layer 420. The mold 419 can be removed in step D to provide patterned surface 440.

Exemplary molds can be constructed from any suitable material, e.g., silicon, nickel, stainless steel, aluminum, polydimethyl siloxane (PDMS), and the like. In some instances, a master mold can be created from any of the above materials using various techniques, such as laser writing, X-ray lithography, UV lithography, e-beam lithography, and mechanical machining, e.g., diamond turning and milling. Such master molds can be used to imprint or stamp a pattern in the first layer or, alternatively, the master mold can be used to form additional molds which can be used to pattern the surface. For example, a master mold could be formed from silicon and used to produce a mold comprising nickel, for instance, by electroplating nickel onto the silicon master mold and then detaching the master mold to form a nickel mold.

While FIG. 4 illustrates stamping with a mold as the technique for forming a patterned on surface 417 of the first layer 420, other techniques can also be used alone or in combination, without limitation, to create patterned surface 440. Exemplary techniques can include, for instance, stamping, embossing, molding, replicating, imprinting (e.g., nano- and micro-imprinting), thermal self-patterning, laser patterning, dewetting, phase separation, and self-assembly processes. In some embodiments, etching may be used to form a pattern on the surface 417. However, in various embodiments, the patterning step may not include etching, for instance, in the case of materials that may be soluble in inorganic acids such as HF and HCl.

The composite comprising substrate 410 with first layer 420 having a patterned surface 440 may optionally be further processed according to further embodiments. For example, as illustrated in FIG. 4, step E may comprise depositing or otherwise overlaying the first layer 420 with a second layer 430. Exemplary methods include, but are not limited to, sol-gel deposition methods and reactive or non-reactive vapor deposition methods, such as CVD, PECVD, sputtering, multi-source thermal evaporation, and e-beam evaporation, to name a few. According to various embodiments, the second layer 430 can be deposited on the first layer 420 such that the second layer has a thickness ranging from about 10 nm to about 10 μm, for example, from about 20 nm to about 5 μm, from about 50 nm to about 2 μm, from about 100 nm to about 1 μm, from about 200 nm to about 900 nm, from about 300 nm to about 800 nm, from about 400 nm to about 700 nm, or from about 500 nm to about 600 nm, including all ranges and subranges therebetween.

In a vapor deposition process, a composite comprising the substrate 410 and first layer 420 can be introduced into a chamber (not shown) along with one or more material sources 413′, which can produce particles, atoms, molecules, or ions 415′ (represented by dashed arrows) that are deposited on the patterned surface 440. While FIG. 4 illustrates a solid material source 413′, it is to be understood that the at least one material source can also comprise a liquid, gas, and/or gel material, without limitation. Moreover, while FIG. 4 illustrates a vapor deposition process, it is to be understood that any suitable deposition technique can be used to form the second layer 430 on the first layer 420.

The second layer 430 may have a patterned top surface 455 according to various embodiments, e.g., as shown in FIG. 4 before optional step F. The interface between the first layer and the second layer can likewise be a patterned interface 445. According to various embodiments, the second layer 430 can be deposited such that it has a thickness (T3, not labeled) greater than or substantially equal to the thickness (T2, not labeled) of the first layer 420 (as shown in FIG. 4). Alternatively, the second layer 430 may have a thickness less than that of the first layer 420 (T3<T2), such that it can flow or be molded into certain regions of the patterned surface 440. For example, the second layer 430 can be deposited only in the valleys of the patterned surface 440 or, in other embodiments, can be preferentially deposited in the valleys such that a thickness of the second layer 430 in the valleys is greater than a thickness of the second layer 430 on the peaks of the patterned surface 440.

As shown in FIG. 4, it may be desirable, in some embodiments, to carry out optional heating step E to planarize patterned top surface 455 so as to produce a substantially planar top surface 450. For example, a composite comprising the substrate 410, first layer 420, and second layer 430 may be heated to a planarizing temperature, which can be any temperature sufficient to cause the material making up the second layer 430 to flow. For example, heat H2 can be applied using any suitable means to raise the temperature of at least the second layer 430 and, optionally, one or more of the first layer 420 and the substrate 410, to the planarizing temperature. For example, the substrate can be placed in a microwave, furnace, or other heating device, or, in other embodiments, the second layer may be heated using a laser or other energy source. While FIG. 4 illustrates the application of heat to the substrate, heat can likewise be applied to the entire article or to only the second layer as desired and without limitation.

According to certain embodiments, the planarizing temperature can be greater than the Tg of the second layer (Tg3). In other embodiments, the structuring temperature can be less than the Tg of the substrate (Tg1) and/or the second layer (Tg2). According to further embodiments, the planarizing temperature can be greater than the softening temperature (Ts) of the second layer (Ts3). In still further embodiments, the planarizing temperature can be greater than about 200° C., such as ranging from about 250° C. to about 1000° C., from about 300° C. to about 900° C., from about 350° C. to about 800° C., from about 400° C. to about 700° C., from about 450° C. to about 600° C., or from about 500° C. to about 550° C., including all ranges and subranges therebetween.

FIG. 5 illustrates an additional method for forming a light-transmitting article according to certain embodiments of the disclosure. Similar to the process illustrated in FIG. 4, step A can comprise coating, laminating, or otherwise overlaying substrate 510 with a first layer 520. Exemplary methods include fusion forming, hot laminating, frit deposition followed by sintering, sol-gel processing, and reactive or non-reactive vapor deposition methods, such as chemical vapor deposition (CVD), plasma-enhanced CVD (PECVD), sputtering, multi-source thermal evaporation, and e-beam evaporation, to name a few. According to various embodiments, an optional layer 521 can be deposited on the substrate 510 prior to the addition of the first layer 520. Exemplary layers 521 can include, but are not limited to, surface energy modifying layers and lubricant layers. Non-limiting examples of suitable materials for use in layer 521 can include molybdenum disulfide (MoS₂), graphite, graphene, polymers, silicones, nitrides, carbons, diamond-like carbons, surface active materials (SAMs), and organic or inorganic fluorine-containing materials, to name a few. According to various embodiments, methods employing a film dewetting process may employ one or more such layers 521.

In certain embodiments, it may be advantageous to control the thickness of the deposited layer 520 so as to promote dewetting or break-up of the layer 520 to form a pattern or structure. For instance, the first layer 520 can be deposited on the substrate 510 (or layer 521) such that the first layer has a thickness ranging from about 10 nm to about 1 μm, for example, from about 50 nm to about 900 nm, from about 100 nm to about 800 μm, from about 200 nm to about 700 nm, from about 300 nm to about 600 nm, or from about 400 nm to about 500 nm, including all ranges and subranges therebetween.

In a vapor deposition process, the substrate 510 and optional layer 521 can be introduced into a chamber (not shown) along with one or more material sources 513, which can produce particles 515 (represented by dashed arrows) that are deposited on the substrate 510 or layer 521. While FIG. 5 illustrates a solid material source 513, it is to be understood that the at least one material source can also comprise a liquid, gas, and/or gel material, without limitation. Moreover, while FIG. 5 illustrates a vapor deposition process, it is to be understood that any suitable deposition technique can be used to form the first layer 520.

As used herein, the term “dewetting” is intended to refer to a process occurring at a solid-liquid or liquid-liquid interface, during which a relatively thin liquid film ruptures or breaks up to form droplets on the surface of a substrate (which can be solid or liquid). Dewetting can be carried out using any known method, for example, thermal dewetting can be performed by heating at least the first layer 520 to a dewetting temperature. As shown in FIG. 5, in steps B1-B3, the composite comprising substrate 510, optional layer 521, and first layer 520 may be heated to a dewetting temperature, which can be any temperature sufficient to cause the material making up the first layer 520 to rupture or break apart into droplets or islands. For example, heat H3 can be applied using any suitable means to raise the temperature of at least the first layer 520 and, optionally, one or more of the optional layer 521 and the substrate 510, to the dewetting temperature. In some embodiments, the substrate can be placed in a microwave, furnace, or other heating device, or, in other embodiments, the second layer may be heated using a laser or other energy source. While FIG. 5 illustrates the application of heat to the substrate, heat can likewise be applied to the entire article or to only the first layer as desired and without limitation.

According to certain embodiments, the dewetting temperature can be greater than the Tg of the first layer (Tg2). In other embodiments, the dewetting temperature can be less than the Tg of the substrate (Tg1). According to further embodiments, the dewetting temperature can be greater than the softening temperature (Ts) of the first layer (Ts2) or greater than the melting temperature (Tm) of the first layer (Tm2). In still further embodiments, the dewetting temperature can be greater than about 250° C., such as ranging from about 250° C. to about 1000° C., from about 300° C. to about 900° C., from about 350° C. to about 800° C., from about 400° C. to about 700° C., from about 450° C. to about 600° C., or from about 500° C. to about 550° C., including all ranges and subranges therebetween.

The dewetting process may produce a variety of results, e.g., depending on the starting materials and process parameters of the dewetting process. For example, a dewetting process B1 may produce an article in which layer 521 is not completely removed and may be broken into islands 521′. As shown in FIG. 5, the first layer 520 may be patterned around such islands to produce patterned surface 540 comprising a plurality of peaks 525 and valleys 523. Alternatively, a dewetting process B2 or B3 may produce an article in which layer 521 is completely or substantially removed. For instance, layer 521 may cause first layer 520 to dewet or break apart while layer 521 itself also breaks into islands 521′ and is removed (process B2-B2′), or layer 521 may cause first layer 520 to dewet or break apart into islands 520′ and layer 521 may be subsequently removed (process B3-B3′). Upon removal of layer 521, the first layer 520 may be patterned on the substrate 510, e.g., a patterned surface 540 comprising a plurality of peaks (or islands) 525 separated by voids 535.

According to various embodiments, if a material making up the first layer 520 is not initially transparent, e.g., a metal, additional processes can be carried out to render the first layer 520 at least partially or fully transparent. For example, in some embodiments, a thin metal film can be applied to a dewetting film on a substrate and subsequently broken apart to form metal islands. The metal islands can then, in certain embodiments, be oxidized or nitridized to render them at least partially or fully transparent.

Subsequent to forming the patterned surface, by any of processes B1-B3, or by any other suitable process, an optional step may be carried out to deposit or otherwise overlay the first layer 520 with a second layer 530. Exemplary methods include, but are not limited to, sol-gel deposition methods and reactive or non-reactive vapor deposition methods, such as CVD, PECVD, sputtering, multi-source thermal evaporation, and e-beam evaporation, to name a few. According to various embodiments, the second layer 530 can be deposited on the first layer 520 such that the second layer has a thickness ranging from about 10 nm to about 10 μm, for example, from about 20 nm to about 5 μm, from about 50 nm to about 2 μm, from about 100 nm to about 1 μm, from about 200 nm to about 900 nm, from about 300 nm to about 800 nm, from about 400 nm to about 700 nm, or from about 500 nm to about 600 nm, including all ranges and subranges therebetween.

According to various embodiments, the second layer 530 may have a thickness less than that of the first layer 520 (T3<T2), such that it can flow or be molded into certain regions of the patterned surface 540. For example, as shown in steps C1 and C1′, the second layer 530 can be deposited only in the valleys 523 or voids 535 of the patterned surface 540 or, in other embodiments, can be preferentially deposited in the valleys such that a thickness of the second layer 530 in the valleys or voids is greater than a thickness of the second layer 530 on the peaks of the patterned surface 540. Alternatively, the second layer 530 can be deposited such that it has a thickness (T3, not labeled) greater than or substantially equal to the thickness (T2, not labeled) of the first layer 520. For instance, steps C2 or C2′ can be carried out to produce a thicker second layer 530, which can optionally be planarized to form a substantially planar surface 550.

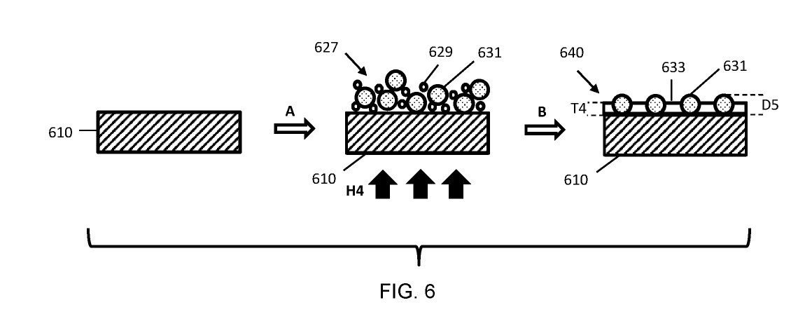

As illustrated in FIG. 6, an alternative method for forming a patterned surface can comprise frit deposition followed by sintering. For example, a frit paste may be prepared by combining glass particles and light-scattering particles, as well as other optional additives, such as solvents and/or binders. The glass particles can be chosen, in some embodiments, from the glass compositions listed in Table I. Furthermore, the glass particles may have a refractive index n4, which can range from about 1.65 to about 2.2, such as from about 1.7 to about 2.15, from about 1.75 to about 2.1, from about 1.8 to about 2.05, from about 1.85 to about 2, or from about 1.9 to about 1.95, including all ranges and subranges therebetween.

The light-scattering particles can comprise, for example, oxides such as silica or titania, which can have a refractive index n5 that is different from that of the glass particles (e.g., at least about 0.1 or about 0.2 higher or lower). In some embodiments, n5>n4, for instance, in the case of titania light-scattering particles (n5=2.4−2.6). In other embodiments n5<n4, for example, in the case of silica light-scattering particles (n5=1.45). The light-scattering particles may have any shape and/or structure as desired to attain a particular light-scattering performance. For example, the light-scattering particles can have anatase or rutile crystal structures and particle sizes ranging, e.g., from about 0.1 μm to about 10 μm, from about 0.2 μm to about 9 μm, from about 0.3 μm to about 8 μm, from about 0.4 μm to about 7 μm, from about 0.5 μm to about 6 μm, from about 0.6 μm to about 5 μm, from about 0.7 μm to about 4 μm, from about 0.8 μm to about 3 μm, or from about 1 μm to about 2 μm, including all ranges and subranges therebetween.

In some embodiments, a glass frit paste 627 comprising glass particles 629 and light-scattering particles 631 can be coated onto a substrate 610 (e.g., step A of FIG. 6) and subsequently sintered by application of heat H4 to form a patterned surface (e.g., step B of FIG. 6). Exemplary sintering temperatures can range, for instance, from about 250° C. to about 1000° C., such as from about 300° C. to about 800° C., from about 400° C. to about 700° C., or from about 500° C. to about 600° C., including all ranges and subranges therebetween. In some embodiments, the sintering temperature can be greater than the glass transition temperature Tg4 of the glass particles, but lower than the glass transition temperature Tg5 of the light-scattering particles. The resulting deposited layer can thus comprise a glass layer 633 having an average thickness T4 and light-scattering particles 631 with particle size D5, wherein D5>T4. The deposited layer thus formed can comprise a patterned surface 640. Alternatively, according to additional embodiments, after sintering, the glass frit paste can be re-heated and subsequently embossed, stamped, imprinted, or the like to form a desired pattern. The composite comprising substrate 610, glass layer 633, and particles 631 can, in some embodiments, be subsequently treated, e.g., by applying one or more additional layers, such as a second layer comprising a third material as discussed above, or by the application of one or more device layers, such as a TCO or OLED layer directly to patterned surface 640.

It will be appreciated that the various disclosed embodiments may involve particular features, elements or steps that are described in connection with that particular embodiment. It will also be appreciated that a particular feature, element or step, although described in relation to one particular embodiment, may be interchanged or combined with alternate embodiments in various non-illustrated combinations or permutations.

It is also to be understood that, as used herein the terms “the,” “a,” or “an,” mean “at least one,” and should not be limited to “only one” unless explicitly indicated to the contrary. Thus, for example, reference to “a valley” includes examples having two or more such valleys unless the context clearly indicates otherwise. Likewise, a “plurality” is intended to denote “more than one.” As such, a “plurality of peaks” includes two or more such peaks, such as three or more such peaks, etc.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In some embodiments, “substantially similar” may denote values within about 10% of each other, such as within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a method that comprises A+B+C include embodiments where a method consists of A+B+C and embodiments where a method consists essentially of A+B+C.

It will be apparent to those skilled in the art that various modifications and variations can be made to the present disclosure without departing from the spirit and scope of the disclosure. Since modifications combinations, sub-combinations and variations of the disclosed embodiments incorporating the spirit and substance of the disclosure may occur to persons skilled in the art, the disclosure should be construed to include everything within the scope of the appended claims and their equivalents.

What is claimed is:

1. A method for forming a light-transmitting article, the method comprising:
providing a substrate comprising a first transparent material having a first glass transition temperature Tg1 and a first refractive index n1;
depositing on the substrate a second transparent material having a second glass transition temperature Tg2 and a second refractive index n2;
heating the substrate to a temperature greater than Tg2; and
forming a patterned surface on the second transparent material,
wherein Tg1>Tg2 and n2>n1.

2. The method of claim 1, wherein Tg1>550° C. and 200° C.<Tg2<600° C.

3. The method of claim 1, further comprising depositing a third transparent material on the patterned surface, the third transparent material having a third glass transition temperature Tg3 and a third refractive index n3.

4. The method of claim 3, wherein Tg1>Tg3 and n3>n1.

5. The method of claim 3, wherein Tg1>Tg2>Tg3 and n3>n2>n1.

6. The method of claim 3, wherein the patterned surface is continuous or semi-continuous and the third transparent material is deposited in one or more valleys of the patterned surface or wherein the patterned surface is semi-continuous or discontinuous and the third transparent material is deposited in one or more voids of the patterned surface.

7. The method of claim 3, further comprising planarizing a top surface of the third transparent material.

8. The method of claim 1, further comprising depositing a dewetting film on the substrate prior to depositing the second transparent material.

9. The method of claim 8, wherein forming the patterned surface on the second transparent material comprises heating the substrate to a temperature and for a time period sufficient to break up the second transparent material and form a semi-continuous or discontinuous patterned surface.

10. The method of claim 1, wherein the second transparent material further comprises light-scattering particles.

11. A method for forming a light-transmitting article, the method comprising:
providing a substrate comprising a first transparent material having a first glass transition temperature Tg1 and a first refractive index n1;
depositing on the substrate a second material having a second glass transition temperature Tg2 and a second refractive index n2;
forming a patterned surface on the second material; and
depositing a third transparent material on the patterned surface, wherein the third material has a third glass transition temperature Tg3 and a third refractive index n1, and
wherein n1, n2, and n3 have different values.

12. The method of claim 11, wherein at least one of: (a) Tg2≧Tg1, (b) n2>n1, (c) Tg2>Tg3, (d) Tg1>Tg3, (e) n3>n2, or (f) n3>n1.

13. The method of claim 11, further comprising depositing a dewetting film prior to depositing the second material, and wherein the second material is deposited as a film having a thickness ranging from about 10 nm to about 1000 nm.

14. The method of claim 11, wherein the patterned surface is continuous or semi-continuous and the third transparent material is deposited in one or more valleys of the patterned surface or wherein the patterned surface is semi-continuous or discontinuous and the third transparent material is deposited in one or more voids of the patterned surface.

15. The method of claim 11, further comprising planarizing a top surface of the third transparent material.

16. An article comprising:
(a) a substrate comprising a first transparent material having a first glass transition temperature Tg1 and a first refractive index n1;
(b) a first layer comprising a second transparent material having a second glass transition temperature Tg2 and a second refractive index n2; and
(c) a second layer comprising a third transparent material having a third glass transition temperature Tg3 and a third refractive index n3,
wherein an interface between the first and second layer is patterned, and
wherein Tg1>Tg2>Tg3 and n3>n2≧n1.

17. The article of claim 16, wherein Tg1>550° C.; 400° C.<Tg2<600° C.; and
200° C.<Tg3<500° C.

18. The article of claim 16, wherein:
(a) the patterned interface is continuous or semi-continuous and the first layer comprises one or more peaks and valleys, and wherein the second layer is disposed in one or more of the valleys, or
(b) the patterned interface is semi-continuous or discontinuous and the first layer comprises one or more peaks separated by voids, and wherein the second layer is disposed in one or more of the voids.

19. The article of claim 18, wherein the article is light-diffusing and the second layer is also disposed on or more of the peaks and has a greater average thickness in the valleys or voids than on the peaks.

20. The article of claim 18, wherein the article is light-extracting, the second layer has a thickness greater than a peak height of the first layer, and the second layer comprises a substantially planar top surface.

21. The article of claim 16, wherein the first layer further comprises light scattering particles.

22. The article of claim 16, wherein n1 ranges from about 1.45 to about 1.55, n2 ranges from about 1.5 to about 1.7, and n3 ranges from about 1.65 to about 2.2.

23. The article of claim 16, further comprising one or more additional layers chosen from the group consisting of transparent conducting oxide, electrode, light-emitting diode, and organic light-emitting diode layers.

24. A display device comprising the article of claim 16.
